(19) United States
(12) Patent Application Publication
(10) Pub. No.: US 2023/0378289 A1
(43) Pub. Date: Nov. 23, 2023

(54) SEMICONDUCTOR DEVICE

(71) Applicant: Samsung Electronics Co., Ltd., Suwon-si (KR)

(72) Inventors: Kyung Soo KIM, Suwon-si (KR); Kyen-Hee LEE, Suwon-si (KR)

(73) Assignee: Samsung Electronics Co., Ltd., Suwon-si (KR)

(21) Appl. No.: 18/318,123

(22) Filed: May 16, 2023

(30) Foreign Application Priority Data
May 18, 2022 (KR) 10-2022-0060564

(51) Int. Cl. H01L 29/417; H01L 29/423; H01L 29/06; H01L 29/775; H01L 29/786; H01L 27/088; H01L 29/18

(52) U.S. Cl. CPC H01L 29/41733; H01L 29/42392; H01L 29/0673; H01L 29/775; H01L 29/78696; H01L 27/088; H01L 29/18

(57) ABSTRACT

A semiconductor device includes a substrate, a two-dimensional material layer on the substrate, the two-dimensional material layer extending in a first direction, a gate structure extending in a second direction intersecting the first direction, the gate structure on the two-dimensional material layer, and a source/drain contact on the substrate. The source/drain contact surrounds each opposing end of the two-dimensional material layer, the source/drain contact includes a first portion in contact with each opposing end of the two-dimensional material layer, the source/drain contact includes a second portion on the first portion, and the second portion has a larger aspect ratio than an aspect ratio of the first portion.

### CROSS-REFERENCE TO RELATED APPLICATION

This application claims priority from Korean Patent Application No. 10-2022-0060564 filed on May 18, 2022 in the Korean Intellectual Property Office, and all the benefits accruing therefrom under 35 U.S.C. 119, the contents of which in its entirety are herein incorporated by reference.

### FIELD

The present disclosure relates to a semiconductor device.

### BACKGROUND

A transistor is used in various integrated circuit elements including a semiconductor device, a memory, a driver IC, or a logic element that performs electrical switching. In order to increase integration of the integrated circuit element, research is being conducted to reduce a size of the transistor while maintaining performance thereof.

When a channel length of the transistor is shortened as the size of the transistor is reduced, mobility of carriers may be lowered due to a short channel effect. For this reason, a two-dimensional material such as transition metal dichalcogenide (TMD) instead of a conventional silicon material may be used in the semiconductor device.

### SUMMARY

Some example embodiments of the inventive concepts provide a semiconductor device having improved performance and reliability.

Purposes according to the inventive concepts are not limited to the above-mentioned purpose. Other purposes and advantages according to the example embodiments that are not mentioned may be understood based on following descriptions, and may be more clearly understood based on example embodiments according to the inventive concepts. Further, it will be easily understood that the purposes and advantages according to the inventive concepts may be realized using means shown in the example embodiments thereof.

According to an example embodiment of the inventive concepts, a semiconductor device includes a substrate, a two-dimensional material layer on the substrate, the two-dimensional material layer extending in a first direction, a gate structure extending in a second direction intersecting the first direction, the gate structure on the two-dimensional material layer, and a source/drain contact on the substrate, the source/drain contact surrounding each opposing end of the two-dimensional material layer, the source/drain contact including a first portion in contact with each opposing end of the two-dimensional material layer, and the source/drain contact including a second portion on the first portion, the second portion having a larger aspect ratio than an aspect ratio of the first portion.

According to the aforementioned and other example embodiments of the inventive concepts, a semiconductor device includes a substrate, a first semiconductor material layer and a second semiconductor material layer on the substrate, the first semiconductor material layer spaced apart from the second semiconductor material layer in a first direction perpendicular to a top face of the substrate, wherein each of the first and second semiconductor material layers includes a two-dimensional material. The device includes a first gate structure on the first semiconductor material layer and a second gate structure on the second semiconductor material layer, the first gate structure spaced apart from the second gate structure in the first direction, a first source/drain contact including a first portion and a second portion, the first portion surrounding one end of the first semiconductor material layer, and the second portion on the first portion, and a second source/drain contact including a third portion and a fourth portion, the third portion surrounding one end of the second semiconductor material layer, and the fourth portion on the third portion, wherein a width of the first portion is greater than a width of the second portion, and wherein a width of the third portion is greater than a width of the fourth portion.

According to the aforementioned and other example embodiments of the inventive concepts, a semiconductor device includes a substrate, a first transistor on the substrate, a first wire structure on the first transistor, the first wire structure in a first interlayer insulating film, and a second transistor on the first wire structure, the second transistor in a second interlayer insulating film. The second transistor includes a first semiconductor material layer spaced apart from a second semiconductor material layer in a vertical direction, wherein each of the first and second semiconductor material layers includes a two-dimensional material, a first gate structure on the first semiconductor material layer and a second gate structure on the second semiconductor material layer, wherein the first and second gate structures are spaced apart from each other in the vertical direction, a first source/drain contact in contact with one end of the first semiconductor material layer, and a second source/drain contact in contact with one end of the second semiconductor material layer. Each of the first and second source/drain contacts includes a first portion in contact with one end of each of the first and second semiconductor material layers, and a second portion on the first portion, the second portion having a larger aspect ratio than an aspect ratio of the first portion.

Other details of the example embodiments are included in the detailed descriptions and drawings.

### BRIEF DESCRIPTION OF THE DRAWINGS

The above and other aspects and features of the inventive concepts will become more apparent by describing in detail illustrative example embodiments thereof with reference to the attached drawings, in which:

FIG. 1 is an illustrative layout diagram for illustrating a semiconductor device according to some example embodiments;

FIG. 2 is an illustrative cross-section view taken along a line A-A′ of FIG. 1;

FIG. 3 is an enlarged view of a P1 portion of FIG. 2;

FIG. 4 is an illustrative cross-section diagram taken along a line B-B′ in FIG. 1;

FIG. 5 is a diagram for illustrating a semiconductor device according to some example embodiments;

FIG. 6 is a diagram for illustrating a semiconductor device according to some example embodiments;

FIG. 7 is an enlarged view of a P2 portion of FIG. 6;

FIG. 8 is a diagram for illustrating a semiconductor device according to some example embodiments;

FIG. 9 is a diagram for illustrating a semiconductor device according to some example embodiments;

FIGS. 10, 11, 12, 13, 14, 15, 16, 17 and 18 are diagrams of intermediate structures corresponding to steps for illustrating a method for manufacturing a semiconductor device according to some example embodiments;

FIGS. 19, 20, 21 and 22 are diagrams of intermediate structures corresponding to steps for illustrating a method for manufacturing a semiconductor device according to some example embodiments; and

FIGS. 23, 24 and 25 are diagrams for illustrating a semiconductor device according to some example embodiments, respectively.

### DETAILED DESCRIPTION

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the example embodiments, numerous specific details are set forth in order to provide a thorough understanding of the inventive concepts. However, it will be understood that the inventive concepts may be practiced without these specific details. In other instances, well-known methods, procedures, components, and circuits have not been described in detail so as not to unnecessarily obscure aspects of the inventive concepts. Examples of various example embodiments are illustrated and described further below. It will be understood that the description herein is not intended to limit the claims to the specific example embodiments described. On the contrary, it is intended to cover alternatives, modifications, and equivalents as may be included within the idea and scope of the inventive concepts.

A shape, a size, a ratio, an angle, a number, etc. disclosed in the drawings for illustrating example embodiments of the inventive concepts are illustrative, and the inventive concepts not limited thereto. The same reference numerals refer to the same elements herein. Further, descriptions and details of well-known steps and elements are omitted for simplicity of the description. Furthermore, in the following detailed description of the example embodiments, numerous specific details are set forth in order to provide a thorough understanding of the inventive concepts. However, it will be understood that the example embodiments may be practiced without these specific details. In other instances, well-known methods, procedures, components, and circuits have not been described in detail so as not to unnecessarily obscure example embodiments of the inventive concepts.

The terminology used herein is for the purpose of describing particular example embodiments only and is not intended to limit the inventive concepts. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the scope of the inventive concepts.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain example embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of the various example embodiments of the inventive concepts may be partially or entirely combined with each other, and may be technically associated with each other or operate with each other. The example embodiments may be implemented independently of each other and may be implemented together in an association relationship. Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Terms as used herein “first direction D1”, “second direction D2” and “third direction D3” should not be interpreted only to have a geometric relationship in which the first direction, the second direction, and the third direction are perpendicular to each other. The “first direction D1”, “second direction D2” and “third direction D3” may be interpreted to have a broader direction within a range in which components herein may work functionally.

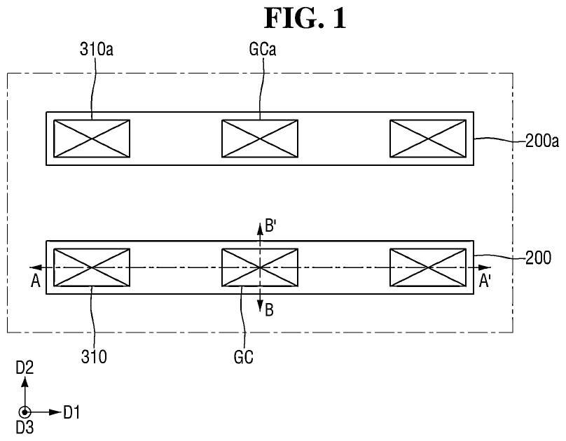

With reference to FIG. 1 to FIG. 4, a description of a semiconductor device according to some example embodiments will be made.

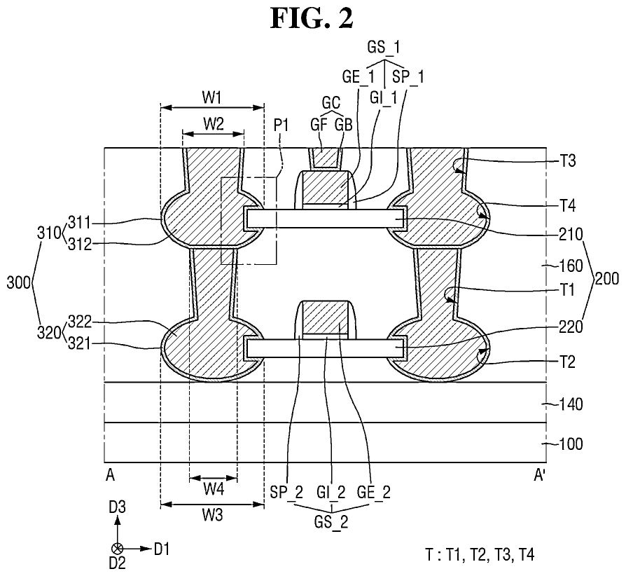

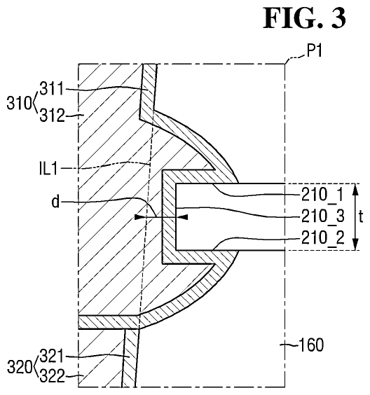

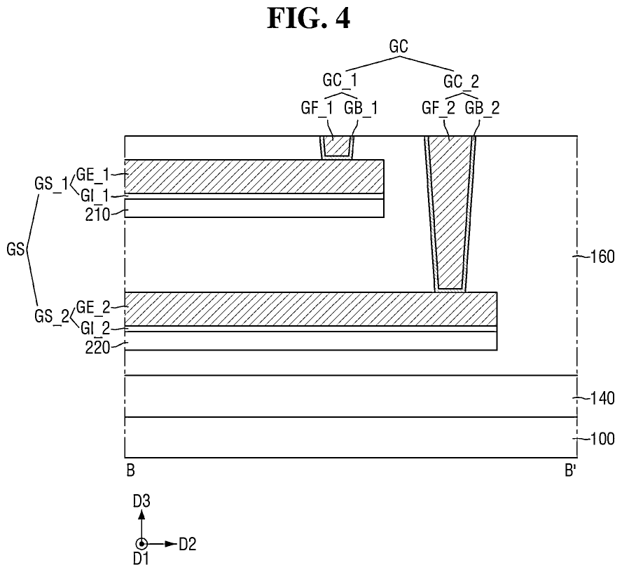

FIG. 1 is an illustrative layout diagram for illustrating a semiconductor device according to some example embodiments. FIG. 2 is an illustrative cross-section view taken along a line A-A′ of FIG. 1. FIG. 3 is an enlarged view of a P1 portion of FIG. 2. FIG. 4 is an illustrative cross-section diagram taken along a line B-B′ in FIG. 1.

Referring to FIG. 1 to FIG. 4, the semiconductor device according to some example embodiments may include a first substrate 100, a first interlayer insulating film 160, a semiconductor material layer 200, a gate structure GS, a source/drain contact 300 and a gate contact GC.

The first substrate 100 may extend in each of the first direction D1 and the second direction D2. In this regard, the first direction D1 may intersect the second direction D2 and the third direction D3. Further, the second direction D2 may intersect the third direction D3. The third direction D3 may be a thickness direction of the first substrate 100.

An etch stop layer 140, the first interlayer insulating film 160, the semiconductor material layer 200, and the source/drain contact 300 to be described later may be disposed on the first substrate 100.

At least one gate structure GS may be disposed on the first substrate 100. Adjacent gate structures GS may be spaced apart from each other in the second direction D2. Accordingly, adjacent gate contacts GC and GCa may be spaced apart from each other in the second direction D2, while adjacent source/drain contacts 310 and 310a may be spaced apart from each other in the second direction D2.

At least one semiconductor material layer 200 may be disposed on the first substrate 100. Adjacent semiconductor material layers 200 and 200a may be spaced apart from each other in the second direction D2.

The first substrate 100 may be embodied as a silicon substrate or an SOI (silicon-on-insulator). Alternatively, the first substrate 100 may include, but is not limited to, silicon germanium, SGOI (silicon germanium on insulator), indium antimonide, a lead telluride compound, indium arsenide, indium phosphide, gallium arsenide, or gallium antimonide.

The etch stop layer 140 is disposed on the first substrate 100. The etch stop layer 140 may be disposed between the first substrate 100 and the first interlayer insulating film 160 to be described later.

The etch stop layer 140 may include a material having an etching selectivity with respect to that of the first interlayer insulating film 160, which will be described later. The etch stop layer 140 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof, but example embodiments are not limited thereto.

The first interlayer insulating film 160 is disposed on the first substrate 100. The first interlayer insulating film 160 may be disposed on the first etch stop film 140. The first interlayer insulating film 160 may be disposed on an area of the source/drain contact 300 except for an area thereof contacting the semiconductor material layer 200 to be described later. The first interlayer insulating film 160 may surround an area of the source/drain contact 300 except for an area thereof in contact with the semiconductor material layer 200 and the etch stop layer 140. The first interlayer insulating film 160 may include, for example, at least one of silicon oxide, silicon nitride, silicon oxynitride, and a low dielectric constant material, but example embodiments are not limited thereto.

First and second gate structures GS_1 and GS_2 may be respectively disposed on first and second semiconductor material layers 210 and 220, which will be described later. The first gate structure GS_1 may be disposed on a top face of the second gate structure GS_2 in the third direction D3. The first and second gate structures GS_1 and GS_2 may include first and second gate electrodes GE_1 and GE_2, first and second gate insulating films GI_1 and GI_2, and first and second gate spacers SP_1 and SP_2, respectively.

In one example embodiment, FIG. 2 shows that the number of gate structures GS is two. However, technical ideas of the inventive concepts are not limited thereto. That is, the number of gate structures GS may be at least three. A plurality of gate structures GS may be sequentially stacked in the third direction D3.

Although not shown, the semiconductor device according to some example embodiments may include a source/drain area disposed adjacent to each of both opposing sides of each of the first and second gate electrodes GE_1 and GE_2. The source/drain area may be connected to the source/drain contact 300 to be described later.

Each of the first and second gate electrodes GE_1 and GE_2 may extend in the second direction D2. Referring to FIG. 4, a plurality of first and second gate electrodes GE_1 and GE_2 may be stacked in the third direction D3 in a step manner In this case, vertical levels in the third direction D3 of the first and second gate electrodes GE_1 and GE_2 may be different from each other. Further, lengths by which the first and second gate electrodes GE_1 and GE_2 extend in the second direction D2 may be different from each other.

Each of the first and second gate electrodes GE_1 and GE_2 may be made of, for example, at least one of metal, conductive metal nitride, conductive metal carbonitride, conductive metal carbide, metal silicide, doped semiconductor material, conductive metal oxynitride and conductive metal oxide, but example embodiments are not limited thereto.

The first gate insulating film GI_1 may be disposed between the first gate electrode GE_1 and the first semiconductor material layer 210. The second gate insulating film GI_2 may be disposed between the second gate electrode GE_2 and the second semiconductor material layer 220. The first and second gate insulating films GI_1 and GI_2 may extend in the second direction D2 while being disposed on the first and second gate electrodes GE_1 and GE_2, respectively.

Each of the first and second gate insulating films GI_1 and GI_2 may include, for example, silicon oxide (SiO₂), silicon oxynitride (SiON), silicon nitride (SiN), or a high dielectric constant material having a higher dielectric constant than that of silicon oxide. The high dielectric constant material may include, for example, at least one of boron nitride, metal oxide, and metal silicon oxide, but example embodiments are not limited thereto.

The first and second gate spacers SP_1 and SP_2 may be disposed on sidewalls of the first and second gate electrodes GE_1 and GE_2, respectively. Each of the first and second gate spacers SP_1 and SP_2 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) and, combinations thereof, but example embodiments are not limited thereto.

Although not specifically illustrated, first and second gate capping patterns may be disposed respectively on top faces of the first and second gate electrodes GE_1 and GE_2 and respectively on top faces of the first and second gate spacers SP_1 and SP_2. Each of the first and second gate capping patterns may include, for example, at least one of silicon nitride (SiN), silicon oxynitride (SiON), silicon oxide (SiO₂), silicon carbonitride SiCN, silicon oxycarbonitride (SiOCN), and combinations thereof, but example embodiments are not limited thereto.

Alternatively, the first gate capping pattern may be disposed between the first gate spacers SP_1. The second gate capping pattern may be disposed between the second gate spacers SP_2. In this case, top faces of the first and second gate capping patterns may be respectively coplanar or substantially coplanar with top faces of the first and second gate spacers SP_1 and SP_2.

The first and second gate contacts GC_1 and GC_2 may be disposed on the first and second gate structures GS_1 and GS_2, respectively. The first and second gate contacts GC_1 and GC_2 may be electrically connected to the first and second gate electrodes GE_1 and GE_2, respectively. Each of the first and second gate contacts GC_1 and GC_2 may extend in the third direction D3.

Referring to FIG. 4, the first and second gate contacts GC_1 and GC_2 may be electrically connected to the first and second gate electrodes GE_1 and GE_2, respectively. In some example embodiments, lengths of the first and second gate contacts GC_1 and GC_2 along the third direction D3 may be different from each other.

The first and second gate contacts GC_1 and GC_2 may respectively include first and second gate barrier layers GB_1 and GB_2 and first and second gate filling films GF_1 and GF_2 on the first and second gate barrier layers GB_1 and GB_2.

Each of the first and second gate barrier layers GB_1 and GB_2 may include, for example, at least one of tantalum (Ta), tantalum nitride (TaN), titanium (Ti), titanium nitride (TiN), and titanium silicon nitride (TiSiN). Each of the first and second gate filling films GF_1 and GF_2 may include, for example, at least one of aluminum (Al), tungsten (W), cobalt (Co), ruthenium (Ru), silver (Ag), gold (Au), manganese (Mn) and molybdenum (Mo), but example embodiments are not limited thereto.

The first and second semiconductor material layers 210 and 220 may be disposed on the first substrate 100 and may extend in the first direction D1 and may be respectively disposed beneath the first and second gate structure GS. The first semiconductor material layer 210 is disposed above the second semiconductor material layer 220 in the third direction D3.

In one example embodiment, FIG. 2 shows only two semiconductor material layers 200. However, technical ideas of the inventive concepts are not limited thereto. That is, at least three semiconductor material layers 200 may be sequentially stacked in the third direction D3.

Referring to FIG. 3, each of the first and second semiconductor material layers 210 and 220 may have a first face 210_1 extending in the first direction D1, a second face 210_2 opposite to the first face 210_1, and a third face 210_3 extending in the second direction D2, and connecting the first face 210_1 and the second face 210_2 to each other. In some example embodiments, the first face 210_1, the second face 210_2, and the third face 210_3 may be respectively referred to as a top face, a bottom face, and a side face.

A first filling film 312 may be filled between the first face 210_1 and a first barrier layer 311 to be described later and between the second face 210_2 and the first barrier layer 311 to be described later. As the first semiconductor material layer 210 invades into the first source/drain contact 310, a dimension from a sidewall of the first source/drain contact 310 to the third face 210_3 may be smaller than a maximum width W1 of a lower portion of the first source/drain contact 310.

A thickness t of each of the first and second semiconductor material layers 210 and 220 may be smaller than 5 nm. In some example embodiments, the thickness t of each of the first and second semiconductor material layers 210 and 220 may mean a length by which each of the first and second semiconductor material layers 210 and 220 extends in the third direction D3.

Each of the first and second semiconductor material layers 210 and 220 may include a two-dimensional semiconductor material. The two-dimensional semiconductor material may include, for example, at least one of graphene, black phosphorous and TMD (Transition Metal Dichalcogenide), but example embodiments are not limited thereto. Graphene has a hexagonal honeycomb structure in which carbon atoms are two-dimensionally bonded to each other. The graphene has higher electrical property and superior thermal property compared to those of silicon (Si), and is chemically stable, and has a large surface area. Black phosphorus may mean a material in which black phosphorous atoms are two-dimensionally bonded to each other.

TMD may include, for example, one transition metal among Mo, W, Nb, V, Ta, Ti, Zr, Hf, Tc, and Re and one chalcogen element among S, Se, and Te. TMD may be expressed, for example, as MX₂, where M represents a transition metal, and X represents a chalcogen element. For example, M may be Mo, W, Nb, V, Ta, Ti, Zr, Hf, Tc, Re, or the like, and X may be S, Se, Te, or the like. Thus, for example, TDM may include MoS₂, MoSe₂, MoTe₂, WS₂, WSe₂, WTe₂, ZrS₂, ZrSe₂, HfS₂, HfSe₂, NbSe₂, ReSe₂, etc., but example embodiments are not limited thereto.

Alternatively, TMD may not be expressed as MX₂. In some example embodiments, for example, TMD may include CuS as a compound of Cu as the transition metal and S as the chalcogen element.

In one example embodiment, TMD may be a chalcogenide material including a non-transition metal. The non-transition metal may include, for example, Ga, In, Sn, Ge, Pb, and the like. In this case, TMD may include a compound of the non-transition metal such as Ga, In, Sn, Ge, and Pb and the chalcogen element such as S, Se, and Te. For example, the TMD may include SnSe₂, GaS, GaSe, GaTe, GeSe, In₂Se₃, InSnS₂, etc., but example embodiments are not limited thereto

In this way, TMD may include one metal element selected from Mo, W, Nb, V, Ta, Ti, Zr, Hf, Tc, Re, Cu, Ga, In, Sn, Ge, and Pb and one chalcogen element selected from S, Se, and Te. However, the materials as mentioned above are merely examples, and other materials may be used as the TMD material.

The two-dimensional semiconductor material has excellent electrical properties. Even when a thickness thereof is in a range of a nanoscale, high mobility of carriers may be realized while the electrical properties are maintained.

The first and second semiconductor material layers 210 and 220 may be respectively disposed under the first and second gate structures GS_1 and GS_2. In some example embodiments, a channel area may be formed in each of the first and second semiconductor material layers 210 and 220. Further, the source/drain area may be formed at each of both opposing ends of each of the first and second semiconductor material layers 210 and 220.

Each of the first and second source/drain contacts 310 and 320 may be disposed on the first substrate 100 and may extend in the third direction D3. The first source/drain contact 310 is disposed above the second source/drain contact 320 in the third direction D3. The first source/drain contact 310 may be connected to the source/drain area formed at the first semiconductor material layer 210. The second source/drain contact 320 may be connected to the source/drain area formed at the second semiconductor material layer 220.

The first source/drain contact 310 may include a plurality of first source/drain contacts 310 which may be spaced apart from each other in the first direction D1 and may respectively contact both opposing ends of the first semiconductor material layer 210. The second source/drain contact 320 may include a plurality of second source/drain contacts 320 which may be spaced apart from each other in the first direction D1 and may respectively contact both opposing ends of the second semiconductor material layer 220.

The first source/drain contacts 310 may respectively surround both opposing ends of the first semiconductor material layer 210. More specifically, the first source/drain contact 310 may surround at least a portion of each of the first and second faces 210_1 and 210_2, and the third face 210_3 of the first semiconductor material layer 210.

The second source/drain contact 320 may surround each of both opposing ends of the second semiconductor material layer 220. More specifically, the second source/drain contact 320 may surround at least a portion of each of a top face and a bottom face, and a side face of the second semiconductor material layer 220.

The first source/drain contact 310 may include a first portion in contact with the first semiconductor material layer 210 and a second portion on the first portion. The first portion may be formed using an isotropic etching process to be described later, while the second portion may be formed using an anisotropic etching process to be described later. Accordingly, a first width W1 of the first portion may be greater than a second width W2 of the second portion. Further, an aspect ratio of the first portion may be smaller than an aspect ratio of the second portion.

The second source/drain contact 320 may include a third portion in contact with the second semiconductor material layer 220 and a fourth portion on the third portion. The third portion may be formed using an isotropic etching process to be described later, while the fourth portion may be formed using an anisotropic etching process to be described later. Accordingly, a third width W3 of the third portion may be greater than a fourth width W4 of the fourth portion. Further, an aspect ratio of the third portion may be smaller than an aspect ratio of the fourth portion.

The first and second source/drain contacts 310 and 320 may be formed inside a trench T at least partially extending through the first interlayer insulating film 160 in the third direction D3.

In some example embodiments, a portion of the trench T may not extend through the first and second semiconductor material layers 210 and 220. Referring to FIG. 3, a first imaginary line IL1 connecting upper and lower sidewalls of a third trench T3 is assumed. For example, the first imaginary line IL1 and the second semiconductor material layer 220 may be spaced apart from each other by a first distance d in the first direction D1.

The first source/drain contact 310 may include a first barrier layer 311 in contact with the first semiconductor material layer 210, and a first filling film 312 on the first barrier layer 311. The second source/drain contact 320 may include a second barrier layer 321 in contact with the second semiconductor material layer 220, and a second filling film 322 on the second barrier layer 321.

The first barrier layers 311 may respectively contact both opposing ends of the first semiconductor material layer 210 and may be respectively formed along surfaces of both opposing ends thereof. More specifically, the first barrier layer 311 may be in contact with at least a portion of each of the first and second faces 210_1 and 210_2, and the third face 210_3 of the first semiconductor material layer 210 and may be formed along and on a surface of at least a portion of each of the first and second faces 210_1 and 210_2, and a surface of the third face 210_3 of the first semiconductor material layer 210.

The second barrier layers 321 may respectively contact both opposing ends of the second semiconductor material layer 220 and may be respectively formed along surfaces of both opposing ends thereof. More specifically, the second barrier layer 321 may be in contact with at least a portion of each of the top face and the bottom face and the side face of the second semiconductor material layer 220 and may be formed along and on a surface of at least a portion of each of the top face and the bottom face and a surface of the side face thereof.

Each of the first and second barrier layers 311 and 321 may include a semimetal material. For example, each of the first and second barrier layers 311 and 321 may include at least one of Ab, Bi, As, Ti, and TiN, but example embodiments are not limited thereto.

Each of the first and second filling films 312 and 322 may have a thickness larger than that of each of the first and second barrier layers 311 and 321. Each of the first and second filling films 312 and 322 may include a conductive material with low resistivity. For example, each of the first and second filling films 312 and 322 may include at least one of Cu and W.

According to the semiconductor device of some example embodiments, when the two-dimensional material is used in the channel area, a contact area between the two-dimensional material layer and the source/drain contact may be increased compared to the prior art, thereby reducing resistance.

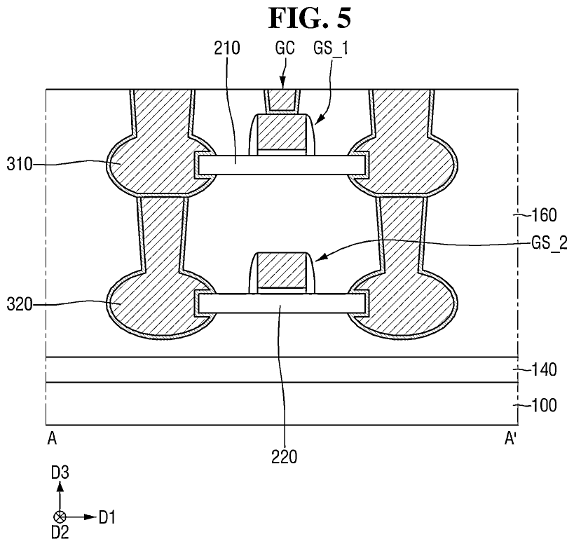

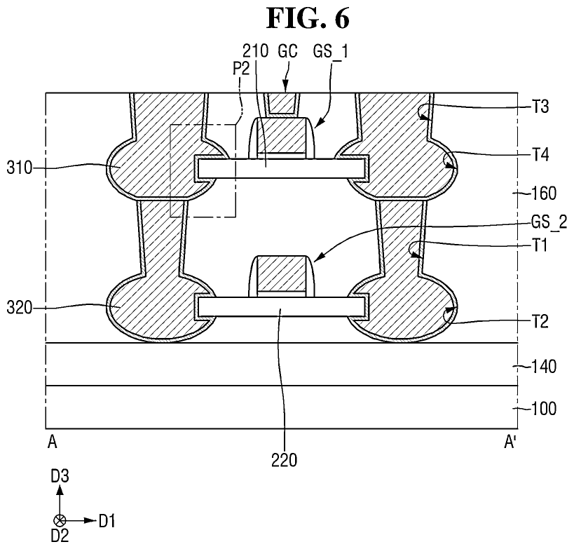

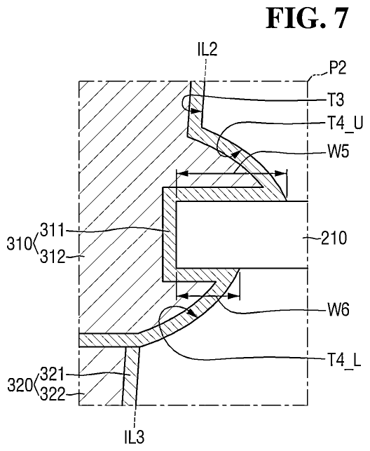

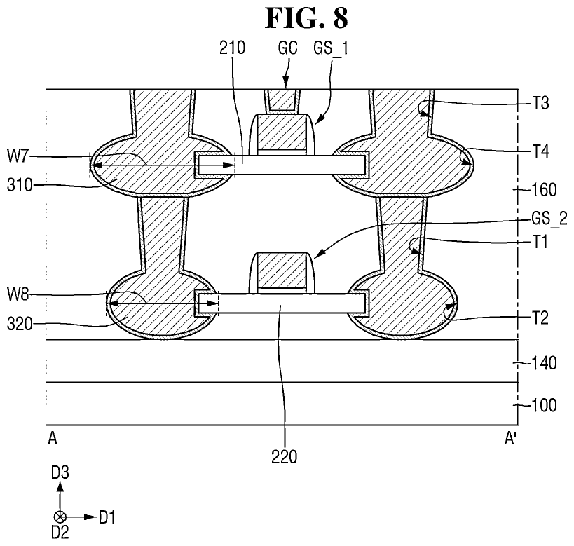

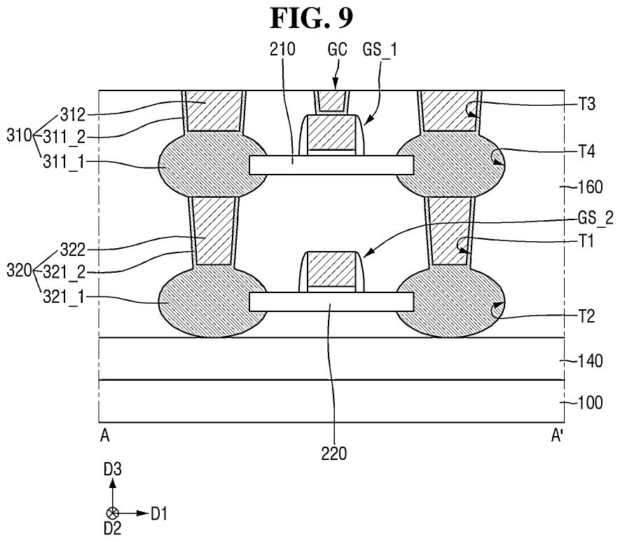

FIG. 5 is a diagram for illustrating a semiconductor device according to some example embodiments. FIG. 6 is a diagram for illustrating a semiconductor device according to some example embodiments. FIG. 7 is an enlarged view of a P2 portion of FIG. 6. FIG. 8 is a diagram for illustrating a semiconductor device according to some example embodiments. FIG. 9 is a diagram for illustrating a semiconductor device according to some example embodiments. For convenience of description, a following description is based on differences thereof from those as described with reference to FIG. 1 to FIG. 4.

Referring to FIG. 5, the etch stop layer 140 may not contact the first and second source/drain contacts 310 and 320. Each of the first and second source/drain contacts 310 and 320 may partially extend through the first interlayer insulating film 160 in the third direction D3.

The first interlayer insulating film 160 may be disposed between the etch stop layer 140 and the first and second source/drain contacts 310 and 320. The first interlayer insulating film 160 may include, for example, at least one of silicon oxide, silicon nitride, silicon oxynitride, and a low dielectric constant material, but example embodiments are not limited thereto.

Alternatively, although not specifically illustrated, an interlayer insulating film other than the first interlayer insulating film 160 may be further disposed between the etch stop layer 140 and the first and second source/drain contacts 310 and 320.

Referring to FIG. 6 and FIG. 7, the third trench T3 may at least partially extend through the first semiconductor material layer 210 in the third direction D3. A second imaginary line IL2 extending from the third trench T3 and a third imaginary line IL3 extending from a sidewall of a first trench T1 may be assumed. The second imaginary line IL2 and the third imaginary line IL3 may coincide with each other. The second imaginary line IL2 may overlap the first semiconductor material layer 210 while the third imaginary line IL3 may non-overlap the first semiconductor material layer 210.

Using an isotropic etching process to be described later, a fourth upper trench T4_U may have a larger area overlapping the first semiconductor material layer 210 than an area by which a fourth lower trench T4_L overlaps the first semiconductor material layer 210. Accordingly, a width W5 of an area of the first source/drain contact 310 in contact with a top face of the first semiconductor material layer 210 may be different from a width W6 of an area of the first source/drain contact 310 in contact with a bottom face of the first semiconductor material layer 210. More specifically, the width W5 of the area of the first source/drain contact 310 in contact with the top face of the first semiconductor material layer 210 may be larger than the width W6 of the area of the first source/drain contact 310 in contact with a bottom face of the first semiconductor material layer 210.

Further, an area by which the first source/drain contact 310 contacts the first semiconductor material layer 210 may be different from an area by which the second source/drain contact 320 contacts the second semiconductor material layer 220. More specifically, the area by which the first source/drain contact 310 contacts the first semiconductor material layer 210 may be larger than the area by which the second source/drain contact 320 contacts the second semiconductor material layer 220.

Referring to FIG. 8, a width of the first trench T1 may be different from a width of the third trench T3. Further, a width of the second trench T2 may be different from a width of the fourth trench T4. For example, a width W7 of the fourth trench T4 may be greater than a width W8 of the second trench T2.

In some example embodiments, a width of the first source/drain contact 310 may be larger than a width of the second source/drain contact 320.

Referring to FIG. 9, a first_first barrier layer 311_1 may fill an entirety of a lower portion of the first source/drain contact 310. A second_first barrier layer 321_1 may fill an entirety of a lower portion of the second source/drain contact 320.

In this case, the lower portion of the first source/drain contact 310 means an area of the first source/drain contact 310 corresponding to the fourth trench T4. The lower portion of the second source/drain contact 320 may mean an area of the second source/drain contact 320 corresponding to the second trench T2.

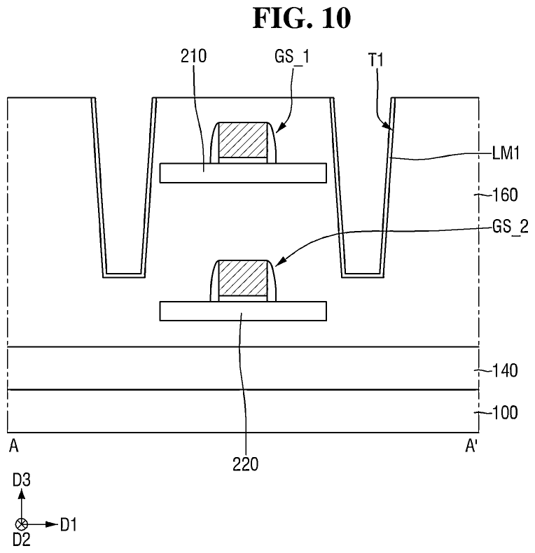

FIG. 10 to FIG. 18 are diagrams of intermediate structures corresponding to steps for illustrating a method for manufacturing a semiconductor device according to some example embodiments. For convenience of description, a following description is based on differences thereof from those as described with reference to FIG. 1 to FIG. 4. Further, for the convenience of description, the descriptions about the first and second gate contacts GC_1 and GC_2 in FIG. 1 to FIG. 4 may be omitted.

Referring to FIG. 10, the first trench T1 is formed by etching the first interlayer insulating film 160 using an anisotropic etching process. In some example embodiments, at least a portion of the first interlayer insulating film 160 may be etched so that the first trench T1 does not come into contact with the first semiconductor material layer 210.

A length of the first trench T1 in the third direction D3 may be larger than a length thereof in the first direction DE The length of the first trench T1 in the first direction D1 may decrease as the first trench extends downwardly in the third direction D3. However, technical ideas of the inventive concepts are not limited thereto.

Thereafter, a first liner material layer LM1 is formed along and on a sidewall and a bottom face of the first trench T1. For example, the first liner material layer LM1 may include silicon nitride (SiN).

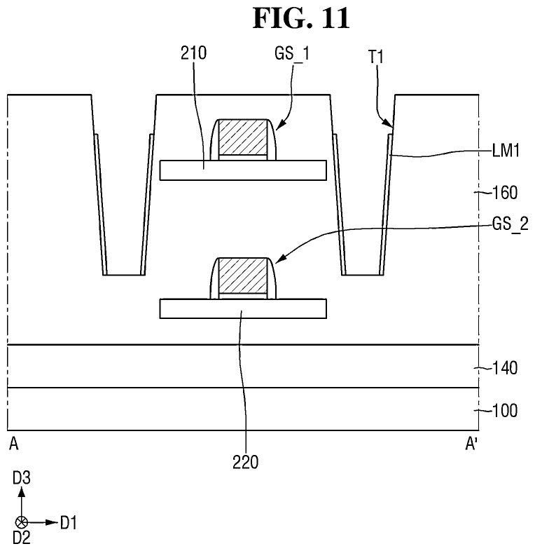

Referring to FIG. 11, at least a portion of the first liner material layer LM1 may be etched using a dry etching process. In some example embodiments, a top portion and a bottom portion of the first liner material layer LM1 may be removed. Accordingly, a portion of the first interlayer insulating film 160 corresponding to a portion of the sidewall and the bottom face of the first trench T1 may be exposed. In the dry etching process, at least a portion of the first liner material layer LM1 may be etched using a substance that selectively removes silicon nitride.

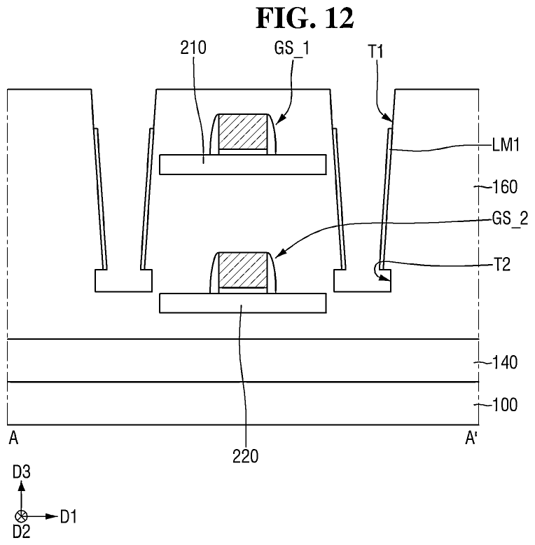

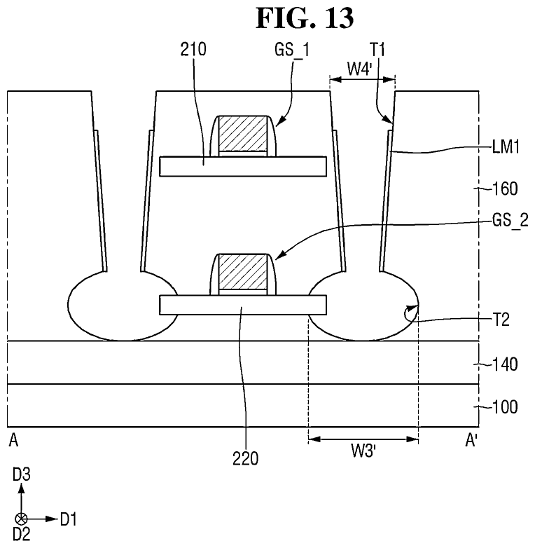

Referring to FIG. 12 and FIG. 13, the second trench T2 is formed by etching the exposed portion of the first interlayer insulating film 160 using an isotropic etching process. A width W3′ along the first direction D1 of the second trench T2 may be larger than a width W4′ along the first direction D1 of the first trench T1. Further, in some example embodiments, a length of the second trench T2 in the first direction D1 may be larger than a length thereof in the third direction D3.

The second semiconductor material layer 220 may be exposed through the second trench T2. The isotropic etching process may be performed, for example, using a wet etching process. In the isotropic etching process, a material having an etch selectivity relative to that of each of the first interlayer insulating film 160 and the second semiconductor material layer 220 may be used.

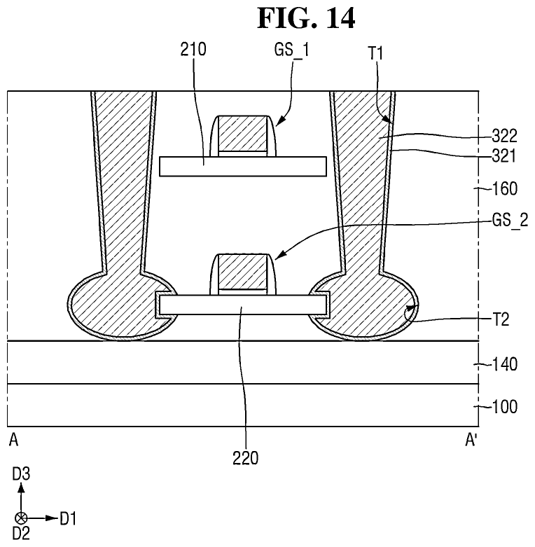

Referring to FIG. 14, an entirety of the first liner material layer LM1 may be removed and then, the second barrier layer 321 may be formed along and on a sidewall of each of the first and second trenches T1 and T2 and a bottom face of the second trench T2. The second barrier layers 321 may be respectively in contact with both opposing ends of the second semiconductor material layer 220 and may be respectively formed along and on the surfaces of both opposing ends thereof. The second barrier layer 321 may include at least one of Ab, Bi, As, Ti, and TiN, but example embodiments are not limited thereto.

Thereafter, the second filling film 322 may be deposited on the second barrier layer 321. The second filling film 322 may include at least one of Cu and W.

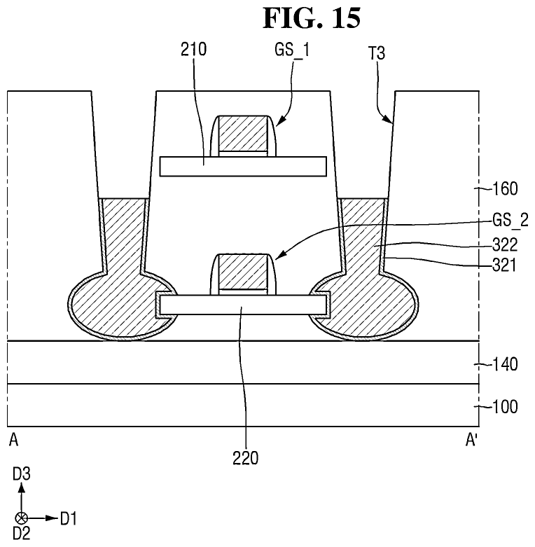

Referring to FIG. 15, an etching process using a substance that selectively removes a metal material may be performed on the second barrier layer 321 and the second filling film 322.

For example, in the etching process, a vertical dimension by which the second barrier layer 321 and the second filling film 322 are removed may be adjusted based on a time duration for which the etching of the second barrier layer 321 and the second filling film 322 is performed. Accordingly, a portion of each of the second barrier layer 321 and the second filling film 322 may be removed to form the third trench T3.

The first interlayer insulating film 160 may be exposed again through the third trench T3. A sidewall of the third trench T3 and a sidewall of the first trench T1 may extend in the same straight line as described above.

However, technical ideas of the inventive concepts are not limited thereto. For example, referring to FIGS. 6 and 7 as described above, the sidewall of the third trench T3 and the sidewall of the first trench T1 may not extend in the same straight line. In some example embodiments, a width along the first direction D1 of the third trench T3 may be different from a width along the first direction D1 of the first trench T1.

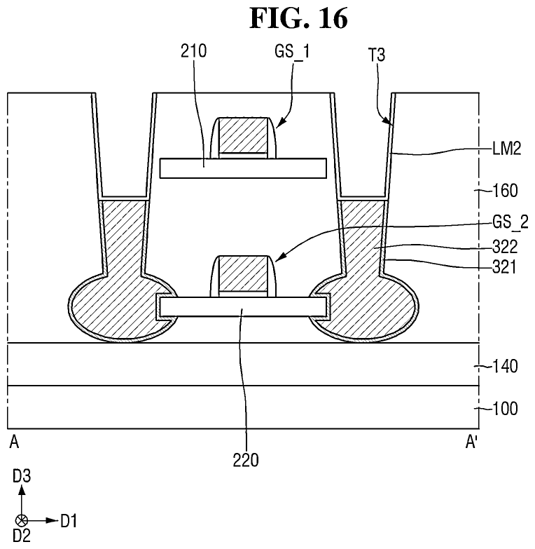

Referring to FIG. 16, a second liner material layer LM2 is formed along and on the sidewall and a bottom face of the third trench T3. A description about a material of the second liner material layer LM2 may be identical with the description about the material of the first liner material layer LM1 as set forth above.

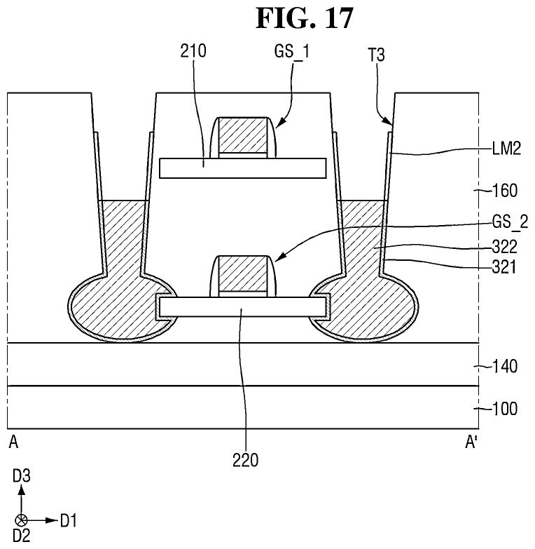

Referring to FIG. 17, at least a portion of the second liner material layer LM2 may be etched using a dry etching process. In some example embodiments, a top portion of the second liner material layer LM2 may be removed. Accordingly, a portion of the first interlayer insulating film 160 corresponding to a portion of the sidewall of the third trench T3 may be exposed. In the dry etching process, at least a portion of the second liner material layer LM2 may be etched using a substance that selectively removes silicon nitride.

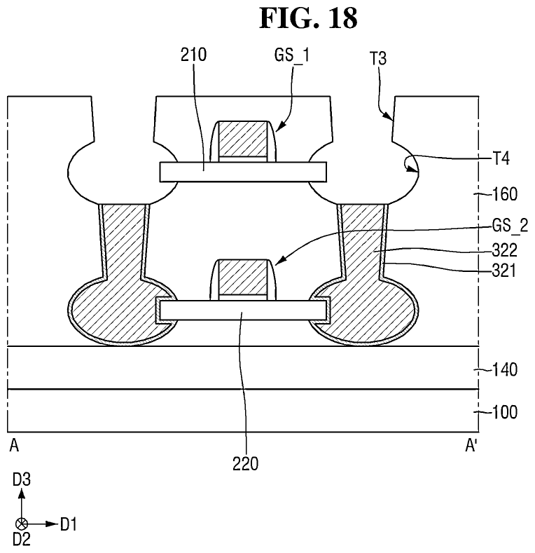

Referring to FIG. 18, the fourth trench T4 is formed by etching the exposed portion of the first interlayer insulating film 160 using an isotropic etching process. A width along the first direction D1 of the fourth trench T4 may be greater than a width along the first direction D1 of the third trench T3. Further, in some example embodiments, a ratio (aspect ratio) between a length of the third trench T3 in the first direction D1 and the length thereof in the third direction D3 may be greater than a ratio (aspect ratio) between a length of the fourth trench T4 in the first direction D1 and a length thereof the third direction D3.

Accordingly, a ratio (aspect ratio) of a length of an upper portion of the first source/drain contact 310 in the third direction D3 to a length of the upper portion of the first source/drain contact 310 in the first direction D1 may be greater than a ratio (aspect ratio) of a lower portion of the first source/drain contact 310 in the third direction D3 to a length thereof in in the first direction D1. Similarly, a ratio (aspect ratio) of a length of an upper portion of the second source/drain contact 320 in the third direction D3 to a length of the upper portion of the second source/drain contact 320 in the first direction D1 may be greater than a ratio (aspect ratio) of a lower portion of the second source/drain contact 320 in the third direction D3 to a length thereof in in the first direction D1.

The first semiconductor material layer 210 may be exposed through the fourth trench T4. The isotropic etching process may be performed, for example, using a wet etching process. In the isotropic etching process, a material having an etch selectivity relative to that of each of the first interlayer insulating film 160 and the first semiconductor material layer 210 may be used.

Thereafter, an entirety of the second liner material layer LM2 may be removed, and then the first barrier layer (e.g., 311 of FIG. 2) may be formed along and on the sidewall of each of the third and fourth trenches T3 and T4 and a bottom face of the fourth trench T4.

The first barrier layer 311 may contact each of both opposing ends of the first semiconductor material layer 210 and may be formed along and on a surface of each of both opposing ends thereof. The first barrier layer 311 may include at least one of Ab, Bi, As, Ti, and TiN, but example embodiments are not limited thereto.

Thereafter, the first filling film 312 may be deposited on the first barrier layer 311. The first filling film 312 may include at least one of Cu and W.

Accordingly, the semiconductor device shown in FIG. 2 may be manufactured.

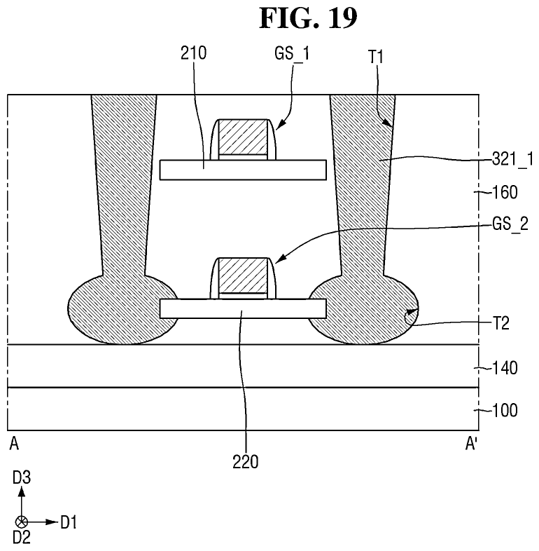

FIG. 19 to FIG. 22 are diagrams of intermediate structures corresponding to steps for illustrating a method for manufacturing a semiconductor device according to some example embodiments. For convenience of description, a following description is based on differences thereof from those as described with reference to FIG. 10 to FIG. 18.

Referring to FIG. 19, the first trench T1 is formed by etching the first interlayer insulating film 160 using an anisotropic etching process.

The first liner material layer may be formed along a sidewall and a bottom face of the first trench T1. Thereafter, at least a portion of the first liner material layer may be etched using a dry etching process. Accordingly, a portion of the first interlayer insulating film 160 corresponding to a portion of the sidewall and the bottom face of the first trench T1 may be exposed.

Thereafter, the second trench T2 is formed by etching the exposed portion of the first interlayer insulating film 160 using an isotropic etching process.

Thereafter, a second_first barrier layer 321_1 is formed to fill an entirety of each of the first and second trenches T1 and T2. The second_first barrier layer 321_1 may include at least one of Ab, Bi, As, Ti, and TiN, but example embodiments are not limited thereto.

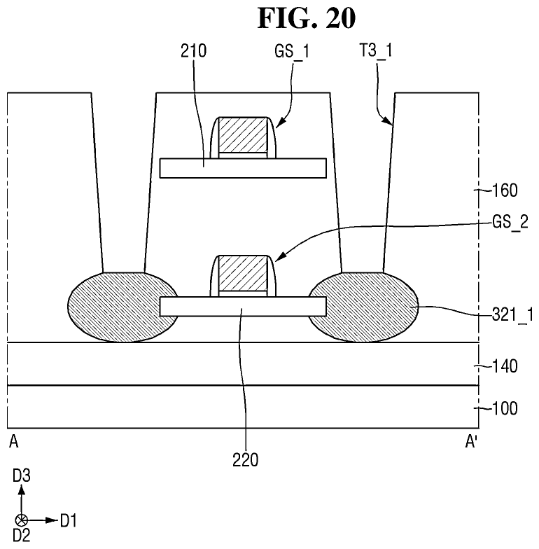

Referring to FIG. 20, an etching process using a substance that selectively removes a metal material may be performed on an upper portion of the second_first barrier layer 321_1. Accordingly, a third_first trench T3_1 may be formed and the first interlayer insulating film 160 may be exposed again.

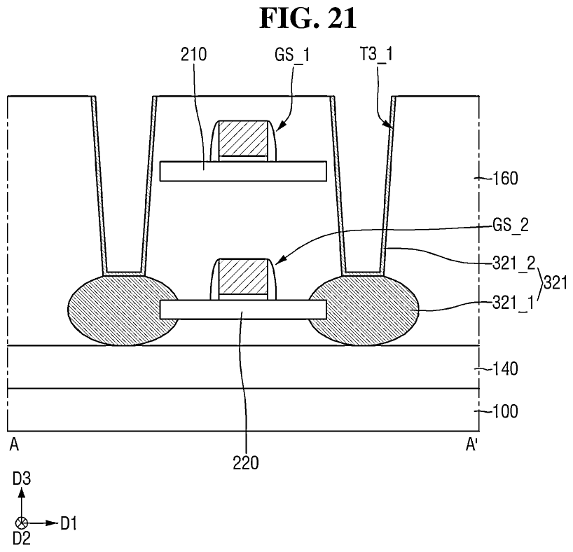

Referring to FIG. 21, a second_second barrier layer 321_2 is formed along and on a sidewall and a bottom face of the third_first trench T3_1. The second_second barrier layer 321_2 may have a thickness smaller than that of the second_first barrier layer 321_1. A bottom face of the second_second barrier layer 321_2 may contact a top face of the second_first barrier layer 321_1. The second_second barrier layer 321_2 may include at least one of Ab, Bi, As, Ti, and TiN, but example embodiments are not limited thereto.

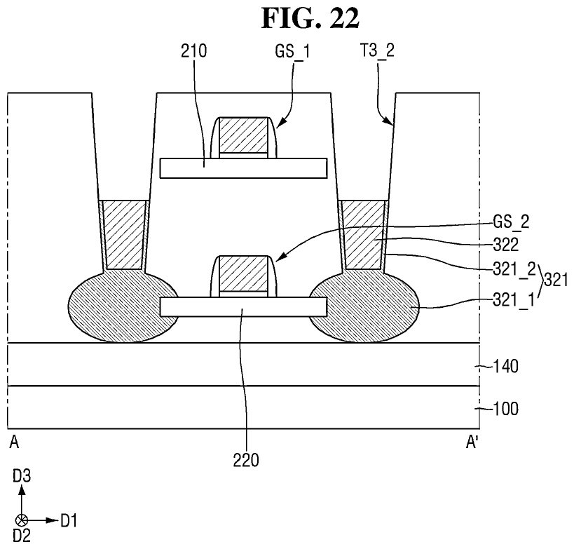

Referring to FIG. 22, the second filling film 322 may be formed on the second_first barrier layer 321_1 and the second_second barrier layer 321_2. The second filling film 322 may include at least one of Cu and W.

Thereafter, an etching process using a substance for selectively removing a metal material may be performed on the second_second barrier layer 321_2 and the second filling film 322.

For example, in the etching process, a vertical dimension by which the second_second barrier layer 321_2 and the second filling film 322 are removed may be adjusted based on a time duration for which the etching of the second_second barrier layer 321_2 and the second filling film 322 is performed. Accordingly, a portion of each of the second_second barrier layer 321_2 and the second filling film 322 may be removed to form a third_second trench T3_2.

Thereafter, a second liner material layer may be formed along and on a sidewall and a bottom face of the third_second trench T3_2, and at least a portion of the second liner material layer may be etched using a dry etching process. Accordingly, a portion of the first interlayer insulating film 160 to the bottom face and a portion of the sidewall of the third_second trench T3_2 may be exposed. The exposed portion of the first interlayer insulating film 160 may be etched using an isotropic etching process to form the fourth trench (e.g., T4 in FIG. 9).

Thereafter, the first_first barrier layer (e.g., 311_1 in FIG. 9) may be formed to fill an entirety of each of the third and fourth trenches T3 and T4. The first_first barrier layer (e.g., 311_1 in FIG. 9) may include at least one of Ab, Bi, As, Ti, and TiN, but example embodiments are not limited thereto.

Thereafter, an etching process using a substance that selectively removes a metal material may be performed on an upper portion of the first_first barrier layer (e.g., 311_1 in FIG. 9). Accordingly, an upper trench exposing the first interlayer insulating film 160 may be formed again.

Thereafter, the first_second barrier layer (e.g., 311_2 in FIG. 9) may be formed along a sidewall and a bottom face of the upper trench. The first_second barrier layer (e.g., 311_2 in FIG. 9) may be formed to have a thickness smaller than that of the first_first barrier layer (e.g., 311_1 in FIG. 9). A bottom face of the first_second barrier layer (e.g., 311_2 in FIG. 9) may contact a top face of the first_first barrier layer (e.g., 311_1 in FIG. 9). The first_second barrier layer (311_2 in FIG. 9) may include at least one of Ab, Bi, As, Ti, and TiN, but example embodiments are not limited thereto.

Thereafter, the first filling film (e.g., 312 in FIG. 9) may be formed on the first_first barrier layer (e.g., 311_1 in FIG. 9) and the first_second barrier layer (e.g., 311_2 in FIG. 9). The first filling film (e.g., 312 in FIG. 9) may include at least one of Cu and W.

Accordingly, the semiconductor device shown in FIG. 9 may be manufactured.

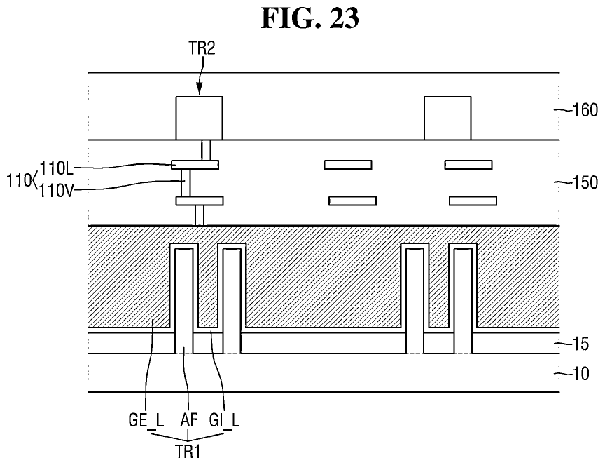

FIG. 23 to FIG. 25 are diagrams for illustrating a semiconductor device according to some example embodiments, respectively. For convenience of description, a following description is based on differences thereof from those as described with reference to FIG. 1 to FIG. 5.

In the drawings related to the semiconductor device according to some example embodiments, illustratively, a fin-shaped transistor (FinFET) including a channel area of a fin-shaped pattern, a transistor including a nanowire or a nanosheet, MBCFET™ (Multi-Bridge Channel Field Effect Transistor) are shown. However, the inventive concepts are not limited thereto. In another example embodiment, the semiconductor device according to some example embodiments may include a vertical transistor (Vertical FET), a tunneling transistor (tunneling FET), or a three-dimensional (3D) transistor. In another example embodiment, the semiconductor device according to some example embodiments may include a planar transistor. In addition, technical ideas of the inventive concepts may be applied to a transistor (2D material based FET) based on a two-dimensional material, and a heterostructure thereof.

FIG. 23 shows an example cut along a lower gate electrode GE_L.

Referring to FIG. 23, the semiconductor device according to some embodiments may include a second substrate 10, a first transistor TR1 on the second substrate 10, a first wire structure 110 on the first transistor TR1, and a second transistor TR2 on the first wire structure 110.

The second substrate 10 may be embodied as a silicon substrate or an (SOI) silicon-on-insulator. Alternatively, the second substrate 10 may include, but is not limited to, silicon germanium, SGOI (silicon germanium on insulator), indium antimonide, a lead telluride compound, indium arsenide, indium phosphide, gallium arsenide, or gallium antimonide.

The first transistor TR1 may include a fin-shaped pattern AF, the lower gate electrode GE_L on the fin-shaped pattern AF, and a lower gate insulating film GI_L between the fin-shaped pattern AF and the lower gate electrode GE_L.

Although not specifically shown, the first transistor TR1 may include a source/drain area disposed on each of both opposing sides of the lower gate electrode GE_L.

The fin-shaped pattern AF may protrude from the second substrate 10. The fin-shaped pattern AF may be a portion of the second substrate 10, or may include an epitaxial layer grown from the second substrate 10. The fin-shaped pattern AF may include, for example, silicon or germanium as an elemental semiconductor material. Further, the fin-shaped pattern AF may include a compound semiconductor, for example, a group IV-IV compound semiconductor or a group III-V compound semiconductor, but example embodiments are not limited thereto.

The group IV-IV compound semiconductor may include, for example, a binary compound including two of carbon (C), silicon (Si), germanium (Ge), and tin (Sn), a ternary compound including three thereof, or a compound obtained by doping a group IV element thereto, but example embodiments are not limited thereto.

The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other, but example embodiments are not limited thereto.

A field insulating film 15 may be formed on the second substrate 10. The field insulating film 15 may be formed on a portion of a sidewall of the fin-shaped pattern AF. The fin-shaped pattern AF may protrude upwardly beyond a top face of the field insulating film 15. The field insulating film 15 may include, for example, an oxide film, a nitride film, an oxynitride film, or a combination thereof, but example embodiments are not limited thereto.

The lower gate electrode GE_L may be disposed on the fin-shaped pattern AF. The lower gate electrode GE_L may intersect the fin-shaped pattern AF.

The lower gate electrode GE_L may include, for example, at least one of metal, conductive metal nitride, conductive metal carbonitride, conductive metal carbide, metal silicide, doped semiconductor material, conductive metal oxynitride, and conductive metal oxide, but example embodiments are not limited thereto.

The lower gate insulating film GI_L may be disposed between the lower gate electrode GE_L and the fin-shaped pattern AF and between the lower gate electrode GE_L and the field insulating film 15. The lower gate insulating film GI_L may include, for example, silicon oxide, silicon oxynitride, silicon nitride, or a high dielectric constant material having a higher dielectric constant than that of silicon oxide. The high dielectric constant material may include, for example, at least one of boron nitride, metal oxide, and metal silicon oxide, but example embodiments are not limited thereto.

The semiconductor device according to some example embodiments may include an NC (negative capacitance) FET using a negative capacitor. In one example embodiment, the lower gate insulating film GI_L may include a ferroelectric material film having ferroelectric characteristics and a paraelectric material film having paraelectric characteristics.

The ferroelectric material film may have negative capacitance, and the paraelectric material film may have positive capacitance. For example, when two or more capacitors may be connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this connection, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O), but example embodiments are not limited thereto.

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn), but example embodiments are not limited thereto. A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), and yttrium (Y), but example embodiments are not limited thereto.

When the dopant is aluminum (Al), the ferroelectric material film may contain an at % of aluminum in a range of about 3 to about 8 at % (atomic %) of aluminum. In this connection, a content of the dopant may be a content of aluminum based on a sum of hafnium and aluminum.

When the dopant is silicon (Si), the ferroelectric material film may contain an at % of silicon in a range about 2 to about 10 at % of silicon. When the dopant is yttrium (Y), the ferroelectric material film may contain an at % of yttrium in a range of about 2 to about 10 at % yttrium. When the dopant is gadolinium (Gd), the ferroelectric material film may contain an at % of gadolinium in a range of about 1 to about 7 at % gadolinium. When the dopant is zirconium (Zr), the ferroelectric material film may contain an at % of zirconium in a range of about 50 to about 80 at % zirconium.

The paraelectric material film may have paraelectric properties. The paraelectric material film may include, for example, at least one of silicon oxide and metal oxide having a high dielectric constant. Although the metal oxide contained in the paraelectric material film may include, for example, at least one of hafnium oxide, zirconium oxide and aluminum oxide. However, the example embodiments are not limited thereto.

The ferroelectric material film and the paraelectric material film may include the same or substantially the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, the example embodiments are not limited thereto. Because a critical thickness exhibiting the ferroelectric properties may be vary based on a type of the ferroelectric material, the thickness of the ferroelectric material film may vary depending on the type of the ferroelectric material.

In one example embodiment, the lower gate insulating film GI_L may include one ferroelectric material film. In another example embodiment, the lower gate insulating film GI_L may include a plurality of ferroelectric material films spaced apart from each other. The lower gate insulating film GI_L may have a stack structure in which a plurality of ferroelectric material films and a plurality of paraelectric material films are alternately stacked with each other.

The first wire structure 110 may be formed in a second interlayer insulating film 150. The first wire structure 110 may be disposed on the lower gate electrode GE_L. At least a portion of the first wire structure 110 may be connected to the lower gate electrode GE_L.

The first wire structure 110 may electrically connect the first transistor TR1 and the second transistor TR2 to be described later to each other. The first wire structure 110 may include a first wire line 110L and a first wire via 110V. The first wire line 110L may include a plurality of first wire lines. The first wire via 110V may include a plurality of first wire vias.

The second transistor TR2 may include the first and second semiconductor material layers 210 and 220, the first and second gate structures GS_1 and GS_2, the first source/drain contact 310 contacting one end of the first semiconductor material layer 210, and the second source/drain contact 320 in contact with one end of the second semiconductor material layer 220 as shown in FIG. 1 to FIG. 9.

According to some example embodiments, the second transistor TR2 may refer to the semiconductor device as described using FIGS. 1 to 9. However, unlike what is shown in FIG. 1 to FIG. 9, the second transistor TR2 may be disposed not on the first substrate 100 but on the first and second interlayer insulating films 150 and 160.

The first and second source/drain contacts 310 and 320 may surround one ends of the first and second semiconductor material layers 210 and 220, respectively. The first and second source/drain contacts 310 and 320 may be respectively formed in trenches extending through at least a portion of the first interlayer insulating film 160.

The first source/drain contact 310 may include the first barrier layer 311 in contact with the first semiconductor material layer 210, and the first filling film 312 on the first barrier layer 311. The second source/drain contact 320 may include the second barrier layer 321 in contact with the second semiconductor material layer 220, and the second filling film 322 on the second barrier layer 321.

An aspect ratio of an upper portion of the first source/drain contact 310 may be greater than an aspect ratio of a lower portion of the first source/drain contact 310. Similarly, an aspect ratio of an upper portion of the second source/drain contact 320 may be greater than an aspect ratio of a lower portion of the second source/drain contact 320.

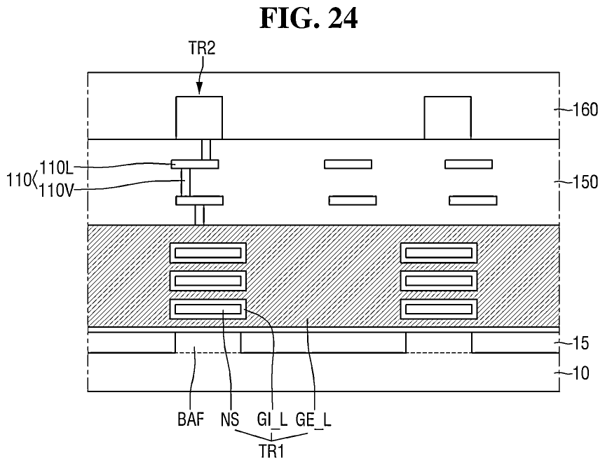

FIG. 24 shows an example cut along the lower gate electrode GE_L. For convenience of description, a following description is based on differences thereof from those as described above using FIG. 23.

Referring to FIG. 24, in the semiconductor device according to some example embodiments, the first transistor TR1 may include a nanosheet NS, the lower gate electrode GE_L surrounding the nanosheet NS, and the lower gate insulating film GI_L between the nanosheet NS and the lower gate electrode GE_L.

The nanosheet NS may be disposed on a lower fin-shaped pattern BAF. The nanosheet NS may be spaced apart from the lower fin-shaped pattern BAF in a vertical direction. Although a transistor TR is illustrated as including three nanosheets NS spaced apart from each other in the vertical direction, the example embodiments are not limited thereto. In another example embodiment, the number of the nanosheets NS arranged in the vertical direction and stacked on the lower fin-shaped pattern BAF may be greater than three or may be smaller than three.

Each of the lower fin-shaped pattern BAF and the nanosheet NS may include, for example, silicon or germanium as an elemental semiconductor material. Each of the lower fin-shaped pattern BAF and the nanosheet NS may include a compound semiconductor, for example, a group IV-IV compound semiconductor or a group III-V compound semiconductor, but example embodiments are not limited thereto. The lower fin-shaped pattern BAF and the nanosheet NS may include the same material, or may include different materials.

The first wire structure 110 may electrically connect the first transistor TR1 and the second transistor TR2 to each other.

The second transistor TR2 may include the first and second semiconductor material layers 210 and 220, the first and second gate structures GS_1 and GS_2, the first source/drain contact 310 contacting one end of the first semiconductor material layer 210, and the second source/drain contact 320 in contact with one end of the second semiconductor material layer 220 as shown in FIG. 1 to FIG. 9.

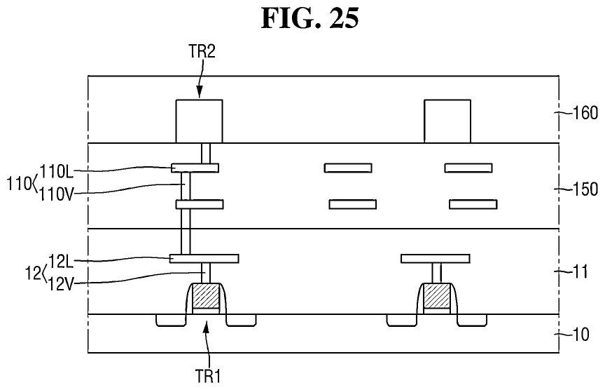

FIG. 25 shows a semiconductor device including a planar transistor by way of example. For convenience of description, a following description is based on differences thereof from those as described above using FIG. 23 and FIG. 24.

Referring to FIG. 25, the semiconductor device according to some example embodiments may include a third interlayer insulating film 11 on the second substrate 10, and a second wire 12 including a second wire line 12L and a second wire via 12V formed in the third interlayer insulating film 11.

The second wire line 12L and the second wire via 12V may electrically connect the first transistor TR1 and the first wire structure 110 to each other. The second wire line 12L may include a plurality of second wire lines. The second wire via 12V may include a plurality of second wire vias.

The second transistor TR2 may be disposed on the first transistor TR1. The second transistor TR2 may be, for example, a planar transistor.

In one example embodiment, although not specifically shown, the semiconductor device according to some example embodiments may mean a semiconductor memory device such as DRAM. The semiconductor memory device may include a cell array area and a peripheral circuit area. A plurality of bit-lines, a plurality of word-lines, and a plurality of memory cell transistors may be disposed in the cell array area. A peripheral circuit for operating the memory cell transistors may be disposed in the peripheral circuit area.

The first and second transistors TR1 and TR2 according to some example embodiments may be included in the semiconductor memory device. In some example embodiments, the first transistor TR1 is disposed in the cell array area of the semiconductor memory device, while the second transistor TR2 may be disposed in the peripheral circuit area. That is, in a semiconductor memory device in which the peripheral circuit area is stacked on the cell array area, the second transistor TR2 may be an element disposed in the peripheral circuit area.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

Although some example embodiments of the inventive concepts have been described above with reference to the accompanying drawings, those of ordinary skill in the art may appreciate that the example embodiments may be implemented in another specific form without changing technical ideas or characteristics of the inventive concepts. Therefore, it should be understood that the example embodiments as described above are not restrictive but illustrative in all respects.

What is claimed is:

1. A semiconductor device comprising:
a substrate;
a two-dimensional material layer on the substrate, the two-dimensional material layer extending in a first direction;
a gate structure extending in a second direction intersecting the first direction, the gate structure on the two-dimensional material layer; and
a source/drain contact on the substrate, the source/drain contact surrounding each opposing end of the two-dimensional material layer, the source/drain contact including a first portion in contact with each opposing end of the two-dimensional material layer, and the source/drain contact including a second portion on the first portion, the second portion having a larger aspect ratio than an aspect ratio of the first portion.

2. The device of claim 1, wherein
the two-dimensional material layer includes a first face extending in the first direction, a second face opposite to the first face, and a third face extending in the second direction, and the third face connecting the first face and the second face to each other, and
the source/drain contact contacts at least a portion of each of the first and second faces, and contacts an entirety of the third face.

3. The device of claim 1, wherein
the source/drain contact includes a barrier layer in contact with the two-dimensional material layer, and
the barrier layer includes at least one of Ab, Bi, As, Ti, or TiN.

4. The device of claim 3, wherein the source/drain contact further includes a filling film on the barrier layer.

5. The device of claim 1, wherein
the device further comprises an interlayer insulating film on the substrate,
the interlayer insulating film is on a first portion of the source/drain contact, the first portion excluding a second portion of the source/drain contact in contact with the two-dimensional material layer, and
the source/drain contact is in a trench extending through at least a portion of the interlayer insulating film.

6. The device of claim 5, wherein the trench does not extend through the two-dimensional material layer.

7. The device of claim 5, wherein the trench extends through the two-dimensional material layer.

8. The device of claim 5, wherein the device further comprises:
a lower wire structure between the substrate and the interlayer insulating film; and
a lower transistor between the lower wire structure and the substrate.

9. The device of claim 1, wherein a thickness of the two-dimensional material layer is less than 5 nm.

10. A semiconductor device comprising:
a substrate;
a first semiconductor material layer and a second semiconductor material layer on the substrate, the first semiconductor material layer spaced apart from the second semiconductor material layer in a first direction perpendicular to a top face of the substrate, wherein each of the first and second semiconductor material layers includes a two-dimensional material;
a first gate structure on the first semiconductor material layer and a second gate structure on the second semiconductor material layer, the first gate structure spaced apart from the second gate structure in the first direction;
a first source/drain contact including a first portion and a second portion, the first portion surrounding one end of the first semiconductor material layer, and the second portion on the first portion; and
a second source/drain contact including a third portion and a fourth portion, the third portion surrounding one end of the second semiconductor material layer, and the fourth portion on the third portion,
wherein a width of the first portion is greater than a width of the second portion,
wherein a width of the third portion is greater than a width of the fourth portion.

11. The device of claim 10, wherein an area by which the first source/drain contact contacts the first semiconductor material layer is different from an area by which the second source/drain contact contacts the second semiconductor material layer.

12. The device of claim 10, wherein
the first source/drain contact includes a first barrier layer in contact with the first semiconductor material layer, and a first filling film on the first barrier layer, and
the second source/drain contact includes a second barrier layer in contact with the second semiconductor material layer, and a second filling film on the second barrier layer.

13. The device of claim 12, wherein
the first barrier layer surrounds a surface of one end of the first semiconductor material layer, and
the second barrier layer surrounds a surface of one end of the second semiconductor material layer.

14. The device of claim 10, wherein
the device further comprises an interlayer insulating film on the substrate,
the interlayer insulating film is on a first portion of each of the first and second source/drain contacts, and the first portion is exclusive of a second portion of each of the first and second source/drain contacts in contact with each of the first and second semiconductor material layers,
the first source/drain contact is in a first trench extending through at least a portion of the interlayer insulating film, and
the second source/drain contact is in a second trench extending through at least a portion of the interlayer insulating film.

15. The device of claim 14, wherein a width of the first trench is different from a width of the second trench.

16. A semiconductor device comprising:
a substrate;
a first transistor on the substrate;
a first wire structure on the first transistor, the first wire structure in a first interlayer insulating film; and
a second transistor on the first wire structure, the second transistor in a second interlayer insulating film,
wherein the second transistor includes
a first semiconductor material layer spaced apart from a second semiconductor material layer in a vertical direction, wherein each of the first and second semiconductor material layers includes a two-dimensional material,
a first gate structure on the first semiconductor material layer and a second gate structure on the second semiconductor material layer, wherein the first and second gate structures are spaced apart from each other in the vertical direction,
a first source/drain contact in contact with one end of the first semiconductor material layer, and
a second source/drain contact in contact with one end of the second semiconductor material layer,
wherein each of the first and second source/drain contacts includes a first portion in contact with one end of each of the first and second semiconductor material layers, and a second portion on the first portion, the second portion having a larger aspect ratio than an aspect ratio of the first portion.

17. The device of claim 16, wherein
the first source/drain contact is in a first trench extending through at least a portion of the second interlayer insulating film, and
the second source/drain contact is inside a second trench extending through at least a portion of the second interlayer insulating film.

18. The device of claim 16, wherein
the first source/drain contact includes a first barrier layer in contact with the first semiconductor material layer, and a first filling film on the first barrier layer, and
the second source/drain contact includes a second barrier layer in contact with the second semiconductor material layer, and a second filling film on the second barrier layer.

19. The device of claim 16, wherein
the first transistor includes a fin-shaped pattern protruding from the substrate in the vertical direction, and a first gate electrode on the fin-shaped pattern, and
the second transistor is electrically connected to the first transistor via the first wire structure.

20. The device of claim 16, wherein
the first transistor includes a nanosheet, and a second gate electrode surrounding the nanosheet, and
the second transistor is electrically connected to the first transistor via the first wire structure.
